(19) United States
(12) Patent Application Publication
(10) Pub. No.: US 2026/0039273 A1
(43) Pub. Date: Feb. 5, 2026

(54) SUPPORT SUBSTRATE, COMPOSITE SUBSTRATE, ELECTRONIC DEVICE, AND MODULE

(71) Applicant: QUANZHOU SANAN INTEGRATED CIRCUIT CO., LTD., Quanzhou (CN)

(72) Inventors: Minghui FANG, Quanzhou (CN); Wenbi CAI, Quanzhou (CN); Zhonghe LIN, Quanzhou (CN); Shihwei HUANG, Quanzhou (CN); Yilin LIU, Quanzhou (CN)

(21) Appl. No.: 19/021,517

(22) Filed: Jan. 15, 2025

(30) Foreign Application Priority Data
Aug. 1, 2024 (CN) 2024110460363

(51) Int. Cl. H03H 9/02; C04B 35/443; H03H 9/00; H03H 9/05; H03H 9/10; H03H 9/25

(52) U.S. Cl. CPC H03H 9/02574; C04B 35/443; H03H 9/0009; H03H 9/02834; H03H 9/0542; H03H 9/0552; H03H 9/1092; H03H 9/25; C04B 2235/3222; C04B 2235/763; C04B 2235/787; C04B 2235/85

(57) ABSTRACT

A support substrate, a composite substrate, an electronic device, and a module are provided, the support substrate is made of a polycrystalline material, a number of small-angle grain boundary with a misorientation angle of 2° to 15° in the support substrate accounts for 1% to 5% of a total number of grain boundaries, and the support substrate with the specific small-angle grain boundary proportion can effectively suppress spurious signals and ensure normal filtering.

### TECHNICAL FIELD

The disclosure relates to the field of electronic device processing and manufacturing technologies, and more particularly to a support substrate, a composite substrate, an electronic device, and a module.

### BACKGROUND

In recent years, with the development of technology, higher performance requirements have been proposed for elastic wave devices, such as surface acoustic wave (SAW) devices. In some SAW devices, such as temperature compensated (TC)-SAW filters, a composite substrate made by bonding a piezoelectric layer substrate and a support substrate is required. Therefore, in the related processes of the SAW devices, the design of the support substrate remains a key research direction. For example, what materials are suitable for making support substrates is also a focus of attention in the related art. For example, single crystal sapphire has excellent thermal conductivity and is widely used in the LED industry. However, due to its single crystal characteristic, the TC-SAW filter made with the single crystal sapphire has always been affected by spurious signals and cannot filter normally. Therefore, how to design the support substrate to reduce the reflection of spurious signals and achieve normal filtering is a problem that needs to be solved.

### SUMMARY

The purpose of the disclosure is to provide a support substrate, a composite substrate, an electronic device, and a module that can reduce spurious signals.

An embodiment of the disclosure provides a support substrate, which is made of a polycrystalline material, and the number of small-angle grain boundaries with a misorientation angle of 2 degrees (°) to 15° in the support substrate accounts for 1% to 5% of the total number of grain boundaries.

An embodiment of the disclosure provides a support substrate, which is made of a polycrystalline material, and the number of small-angle grain boundaries with a misorientation angle of 2° to 15° is greater than or equal to 5 in any metering area on any surface of the support substrate; and the metering area is an area with a length of 150 micrometers (μm) and a width of 150 μm.

An embodiment of the disclosure provides a composite substrate, which includes the support substrate described in any one of the foregoing, and further includes a piezoelectric layer, and the piezoelectric layer is disposed on the support substrate.

An embodiment of the disclosure provides an electronic device, which includes the support substrate or the composite substrate described in any one of the foregoing.

An embodiment of the disclosure provides a module, which includes a wiring substrate, multiple external connection terminals, an integrated circuit component, an inductor, a sealing part, and the electronic device described in the foregoing.

The embodiments of the disclosure have at least one or more beneficial effects as follows: the support substrate with the special grain boundary proportion can effectively reduce the energy of longitudinal wave transmission, thereby effectively reducing the reflection of spurious signals, realizing normal filtering, and being applicable to frequency bands above 3.5 gigahertz (GHz).

### BRIEF DESCRIPTION OF DRAWINGS

The patent or application file contains at least one drawing executed in color. Copies of this patent or patent application publication with color drawings will be provided by the Office upon request and payment of the necessary fee.

Color drawings have been submitted in this application. The color drawings are necessary as the only practical medium by which aspects of the claimed subject matter may be accurately conveyed. For example, the color drawings are used to clearly differentiate between grains that are distinguished by color, and to differentiate grain boundaries.

The specific embodiments of the disclosure will be described in detail with reference to the accompanying drawings.

FIG. 1 illustrates a structural schematic diagram of a support substrate provided by an embodiment of the disclosure.

FIG. 2 illustrates a schematic diagram of a microstructure of a metering area of the support substrate provided by an embodiment of the disclosure.

FIG. 3 illustrates an inverse pole figure (IPF) coloring diagram of the support substrate in FIG. 2.

FIG. 4 illustrates a schematic distribution diagram of misorientation angles of grain boundaries of the support substrate in FIG. 2.

FIG. 5 illustrates a schematic diagram of a microstructure of a metering area of another support substrate provided by an embodiment of the disclosure

FIG. 6 illustrates an IPF coloring diagram of the support substrate in FIG. 5.

FIG. 7 illustrates a schematic distribution diagram of misorientation angles of grain boundaries of the support substrate in FIG. 5.

FIG. 8 illustrates a schematic diagram of a microstructure of a metering area of still another support substrate provided by an embodiment of the disclosure.

FIG. 9 illustrates an IPF coloring diagram of the support substrate in FIG. 8.

FIG. 10 illustrates a schematic distribution diagram of misorientation angles of grain boundaries of the support substrate in FIG. 8.

FIG. 11 illustrates a schematic comparison diagram of spurious suppression effects of support substrates provided by different embodiments of the disclosure.

FIG. 12 illustrates a structural schematic diagram of a composite substrate provided by an embodiment of the disclosure.

FIG. 13 illustrates a structural schematic diagram of an electronic device provided by an embodiment of the disclosure.

FIG. 14 illustrates a structural schematic diagram of another electronic device provided by an embodiment of the disclosure.

FIG. 15 illustrates a structural schematic diagram of still another electronic device provided by an embodiment of the disclosure.

FIG. 16 illustrates a structural schematic diagram of even still another electronic device provided by an embodiment of the disclosure.

FIG. 17 illustrates a structural schematic diagram of a module provided by an embodiment of the disclosure.

### DETAILED DESCRIPTION OF EMBODIMENTS

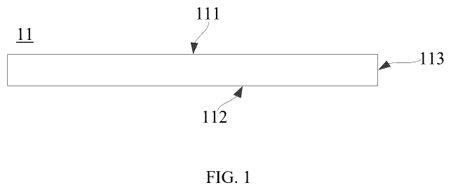

As illustrated in FIG. 1, an embodiment of the disclosure provides a support substrate 11. The support substrate 11 is made of a polycrystalline material, and multiple grains in the support substrate 11 have different crystal orientations and are connected with each other through grain boundaries, that is, the grain boundary is an interface between the grains. Specifically, an included angle of crystal orientations between any two adjacent grains is a misorientation angle, and the corresponding grain boundaries can be divided into small-angle grain boundaries and non-small-angle grain boundaries according to the values of the misorientation angles, in which the grain boundaries with the misorientation angle of 2° to 15° are called the small-angle grain boundaries, and the grain boundaries with the misorientation angle greater than 15° and the grain boundaries with the misorientation angle less than 2° are collectively called the non-small-angle grain boundaries. In the support substrate 11 provided by the embodiment of the disclosure, the number of the small-angle grain boundaries accounts for a total number of grain boundaries (also referred to as a proportion of the small-angle grain boundaries) is 1% to 5%, for example, it can be 1%, 2%, 3%, 4%, etc., and the corresponding number of the non-small-angle grain boundaries (including those with the misorientation angle of less than 2° and those with the misorientation angle greater than) 15° accounts for the total number of the grain boundaries (referred to as a proportion of the non-small-angle grain boundaries) is 95% to 99%, for example, the proportion of the small-angle grain boundaries is 2%, and the proportion of the non-small angle grain boundaries is 98%; for example, the proportion of the small-angle grain boundaries is 3%, and the proportion of the non-small-angle grain boundaries is 97%. Of course, the above is only an example, and this embodiment is not limited to this.

Specifically, the polycrystalline material is, for example, any one selected from the group consisting of polycrystalline magnesia-alumina spinel, polycrystalline sapphire, polycrystalline aluminum nitride, polycrystalline magnesium oxide and polycrystalline quartz.

Specially, the value of the misorientation angle and the number of the grain boundaries in the support substrate 11 can be obtained by obtaining a microstructure diagram on the support substrate 11 through electron back scatter diffraction (EBSD) technology, and then performing IPF coloring on the microstructure diagram. The IPF coloring is a method used to characterize crystal orientation in material science, it shows the orientation information of the crystal in color on the polar diagram, so that the observer can intuitively identify the texture characteristics of the crystal.

Experiments show that the support substrate 11 with the special proportion of grain boundaries provided by the embodiment of the disclosure can effectively reduce the energy of longitudinal wave transmission, further effectively reducing the reflection of spurious signals, and realizing normal filtering, and can be applied to the frequency band above 3.5 GHZ.

Referring to FIG. 1, the support substrate 11 has, for example, a main support surface 111, a back surface 112 opposite to the main support surface 111, and a side surface 113 located between the main support surface 111 and the back surface 112. The main support surface 111 can be used to support the piezoelectric layer.

Specifically, in some embodiments, the number of small-angle grain boundaries in a transverse section or transverse surface of the support substrate 11 accounts for 1% to 5% of the total number of the grain boundaries. More specifically, the proportion of the small-angle grain boundaries in the transverse section or transverse surface of the support substrate 11 may be 3% to 4%. The transverse section can be any section on the support substrate 11 parallel to the main support surface 111. The transverse surface is the main support surface 111 or another surface parallel to the main support surface 111, for example, the back surface 112 is parallel to the main support surface 111, and the transverse surface may be the back surface 112. That is, in some embodiments, the proportion of the small-angle grain boundaries on the main support surface 111 in the support substrate 11 is 1% to 5%. In some embodiments, the proportion of the small-angle grain boundaries on the back surface 112 in the support substrate 11 is 1% to 5%. In some embodiments, the proportion of the small-angle grain boundaries in any section of the support substrate 11 parallel to the main support surface 111 is 1% to 5%.

In some embodiments, the number of the small-angle grain boundaries on any surface of the support substrate 11 (that is, any one of the main support surface 111, the back surface 112 and the side surface 113) accounts for 1% to 5% of the total number of the grain boundaries. That is, observing the grain boundaries on any surface of the support substrate 11, the number of the small-angle grain boundaries accounts for 1% to 5%.

More specifically, the number of the small-angle grain boundaries on any surface of the support substrate 11 accounts for 3% to 4% of the total number of the grain boundaries, and a better spurious reduction effect can be achieved. Referring to FIG. 11, spurious signals of a single crystal sapphire substrate and the support substrate 11 of the disclosure are compared in FIG. 11. In FIG. 11, #1 represents the sapphire substrate, #2, #3 and #4 represent the support substrates 11 provided by the disclosure, and the grain size of grains in #2 is in a range of 20 μm to 30 μm, and the small-angle grain boundary accounts for 3.2%. The grain size of grains in #3 is in a range of 15 μm to 20 μm, and the small-angle grain boundary accounts for 3.5%. The grain size of grains in #4 is in a range of 5 μm to 10 μm, and the small-angle grain boundary accounts for 3.7%. In FIG. 11, the abscissa is frequency, its unit is megahertz (MHz), and the ordinate is admittance, its unit is decibel (dB), and the gray dashed arrow indicates the frequency boundary of 1600 MHZ. According to FIG. 11, it can be seen that the spurious signals with small-angle grain boundaries accounting for 3.2% to 3.7% meets the use requirements, and the spurious suppression effect is the best when the small-angle grain boundaries account for 3.7%.

In some embodiments, in any metering area on any surface of the support substrate 11, the number of the small-angle grain boundaries is greater than or equal to 5, the metering area is an area with a length of 150 μm and a width of 150 μm. That is, an area of 150 μm*150 μm is randomly selected on any surface of the support substrate 11 for observation, and the observed small-angle grain boundaries are all greater than or equal to 5.

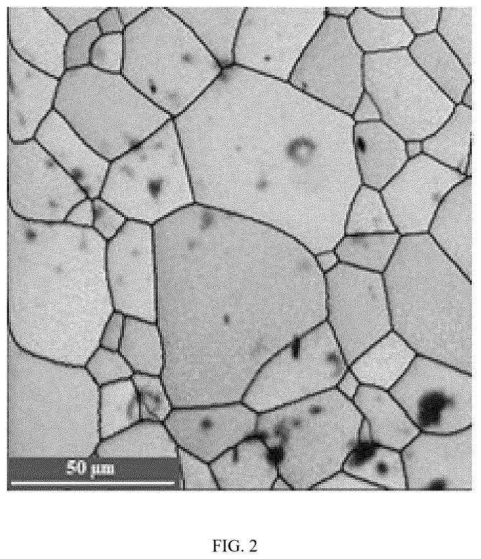

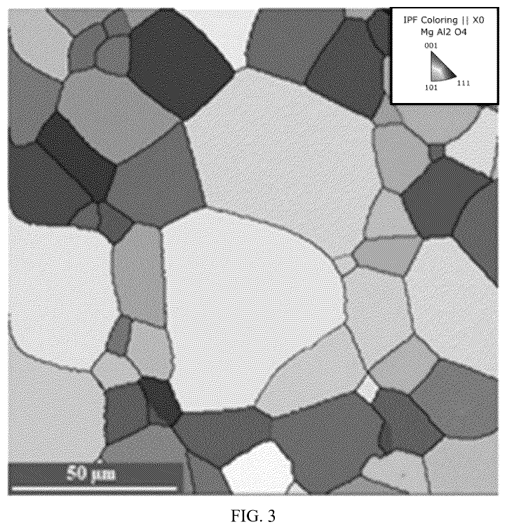

As shown in FIG. 2 and FIG. 3, FIG. 2 illustrates an image of a microstructure of a metering area on a certain transverse surface of a support substrate 11 (made of polycrystalline magnesia-alumina spinel) provided by this embodiment, and FIG. 3 illustrates an image after IPF coloring treatment. In FIG. 3, the colored parts are the grains, the outline of the grain is the grain boundary. The closer the colors of two adjacent grains are in FIG. 3, the smaller the misorientation angle corresponding to the grain boundary between the two grains is. For clearer representation, small-angle grain boundaries are marked with red lines in FIG. 2, as shown in FIG. 2, the number of the small-angle grain boundaries is six.

In some embodiments, the grain size of grains in the support substrate 11 is in a range of 1 μm to 100 μm. Specifically, as shown in FIGS. 2 and 3, the grain size of the grains is in a range of 10 μm to 100 μm. For example, there are grains with different grain sizes such as 10 μm, 25 μm, 40 μm, 50 μm, 60 μm and 100 μm in the support substrate 11, and the grain size of the smallest grain is not less than 10 μm (greater than or equal to 10 μm), and the grain size of the largest grain is not greater than 100 μm (less than or equal to 100 μm).

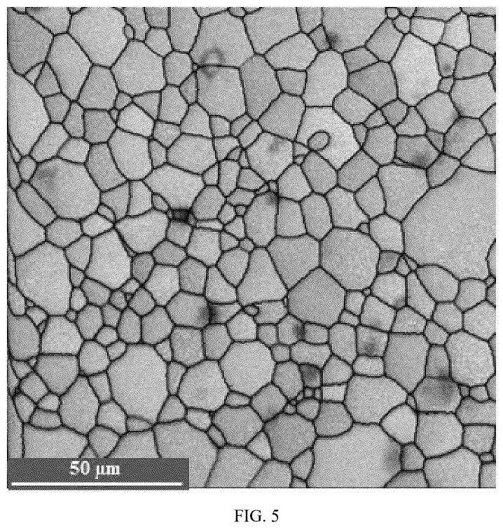

In a further embodiment, the grain size of the grains in the support substrate 11 is in a range of 5 μm to 60 μm. For example, there are grains with different grain sizes such as 5 μm, 10 μm, 20 μm, 25 μm, 40 μm and 60 μm in the support substrate 11, the grain size of the smallest grain is not less than 5 μm (greater than or equal to 5 μm), the grain size of the largest grain is not greater than 60 μm (less than or equal to 60 μm), and the number of small-angle grain boundaries in any metering area on any surface of the support substrate 11 is greater than or equal to 25. That is, an area of 150 μm*150 μm is randomly selected in the support substrate 11 with a grain size of 5 μm to 60 μm for observation, and the number of observed small-angle grain boundaries is greater than or equal to 25. Referring to FIG. 5 and FIG. 6, FIG. 5 is an image of a microstructure of an area of 150 μm*150 μm in a transverse surface of a support substrate 11 (made of polycrystalline magnesia-alumina spinel) with a grain size of 5 μm to 60 μm, and FIG. 6 is an image after the area in FIG. 5 is treated by IPF coloring. The closer the colors of two adjacent grains in FIG. 6, the smaller the misorientation angle corresponding to the grain boundary between the two adjacent grains. Small-angle grain boundaries are marked with red lines in FIG. 5, and the number of obvious small-angle grain boundaries in FIG. 5 is more than 25.

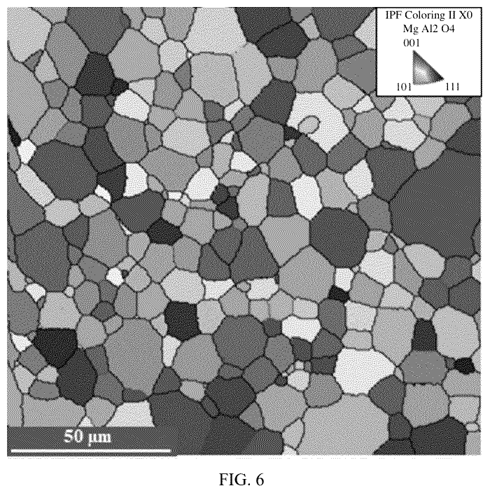

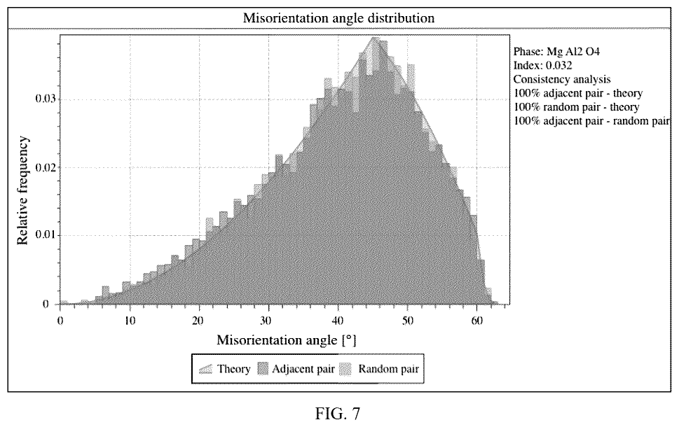

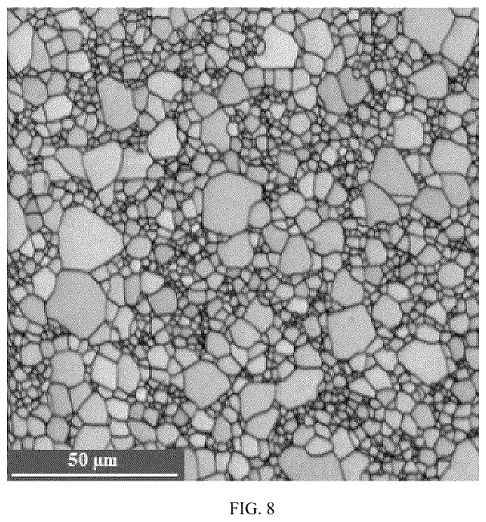

In another embodiment, the grain size of the grains in the support substrate 11 is in a range of 1 μm to 5 μm. For example, there are grains with different grain sizes such as 1 μm, 2 μm, 3 μm and 5 μm in the support substrate 11, the grain size of the smallest grain is not less than 5 μm (greater than or equal to 5 μm), the grain size of the largest grain is not greater than 60 μm (less than or equal to 60 μm), and the number of small-angle grain boundaries in any metering area on any surface of the support substrate 11 is greater than or equal to 40. That is, an area of 150 μm*150 μm is randomly selected on any surface of the support substrate 11 for observation, and the number of observed small-angle grain boundaries is greater than or equal to 40. Referring to FIG. 8 and FIG. 9, FIG. 8 is an image of a microstructure of an area of 150 μm*150 μm in a transverse surface of a support substrate 11 (made of polycrystalline magnesia-alumina spinel) with a grain size of 1 μm to 5 μm, and FIG. 9 is an image of the area in FIG. 8 treated by IPF coloring. The closer the colors of two adjacent grains in FIG. 9, the smaller the misorientation angle corresponding to the grain boundary between the two adjacent grains. Small-angle grain boundaries are marked with red lines in FIG. 8, and the number of obvious small-angle grain boundaries in FIG. 8 is more than 40.

In some embodiments, in any metering area on any surface of the support substrate 11, the number of small-angle grain boundaries accounts for 1% to 5% of the total number of grain boundaries. That is, an area of 150 μm*150 μm is randomly selected on any surface of the support substrate 11 for observation, and the observed proportion of small-angle grain boundaries is in the range of 1% to 5%. That is, the support substrate 11 not only has a specific proportion of small-angle grain boundaries, but also has a uniform distribution of small-angle grain boundaries, which has a better spurious suppression effect. More specifically, the number of small-angle grain boundaries in any metering area on any surface of the support substrate 11 accounts for 3% to 4% of the total number of grain boundaries. For example, according to the measured results in FIGS. 2 and 3, the proportion of small-angle grain boundaries is 3.2%, and the proportion of non-small angle grain boundaries is 96.8%. According to the measured results in FIGS. 5 and 6, the proportion of small-angle grain boundaries is 3.45%, and the proportion of non-small angle grain boundaries is 96.55%. According to the measured results in FIGS. 8 and 9, the proportion of small-angle grain boundaries is 3.7%, and the proportion of non-small angle grain boundaries is 96.3%. In the above embodiments, the proportion of small-angle grain boundaries is in the range of 3% to 4%.

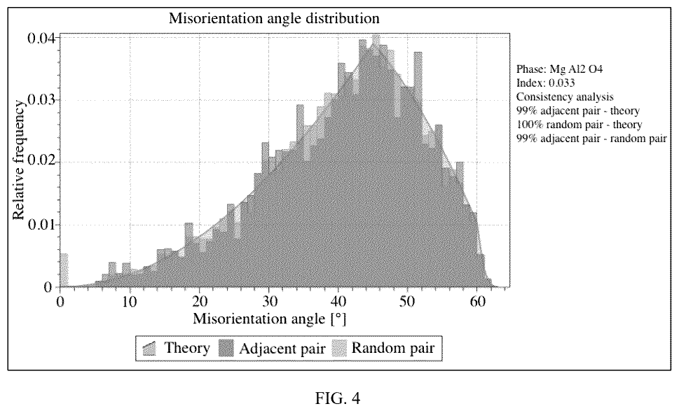

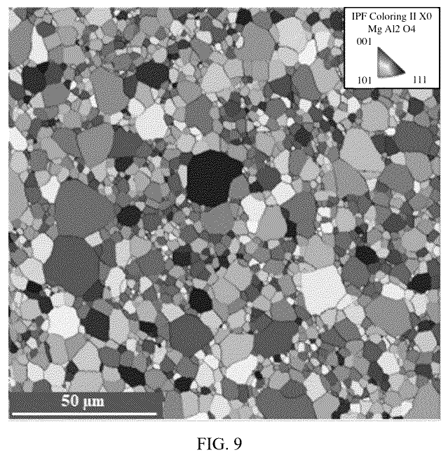

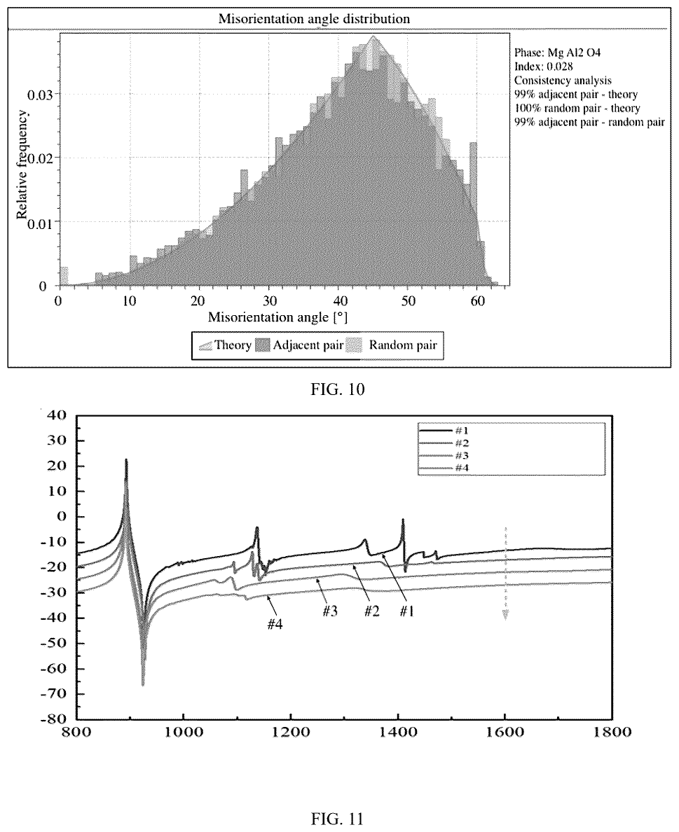

In some embodiments, a distribution peak of the misorientation angle in the support substrate 11 is in the range of 30° to 60°. In a more specific embodiment, the distribution peak of the misorientation angle is in the range of 40° to 50°. The distribution peak value of the misorientation angle means that the number of grain boundaries with the misorientation angle as the distribution peak value accounts for the largest proportion in the total number of grain boundaries on the support substrate 11. For example, the grain boundaries with the misorientation angle of 45° account for the largest proportion in the total number of grain boundaries on the support substrate 11, so the distribution peak value of the misorientation angle is 45°. FIG. 4 illustrates the distribution data diagram of the misorientation angles in the metering area shown in FIGS. 2 and 3, and FIG. 7 illustrates the distribution data diagram of the misorientation angles in the metering area shown in FIGS. 5 and 6. FIG. 10 illustrates the distribution data diagram of misorientation angles in the metering area shown in FIGS. 8 and 9. In FIG. 4, FIG. 7 and FIG. 10, the abscissa is the value of the misorientation angle, and the ordinate is the relative frequency of the misorientation angle corresponding to the value of the abscissa, and the relative frequency is the proportion of the grain boundaries with the misorientation angle in the total number of grain boundaries. For a certain coordinate point, the higher the value of the ordinate, the more grain boundaries whose misorientation angle is the abscissa value corresponding to this point, and the value of the misorientation angle corresponding to the peak value in FIG. 4 is about 46°, indicating that there are the most grain boundaries with the misorientation angle of about 46° in the metering area shown in FIGS. 2 and 3. The value of the misorientation angle corresponding to the peak value in FIG. 7 is about 45°, indicating that there are most grain boundaries with the misorientation angle of about 45° in the metering area shown in FIGS. 5 and 6. The value of the misorientation angle corresponding to the peak value in FIG. 10 is about 45°, indicating that there are most grain boundaries with the misorientation angle of about 45° in the metering area shown in FIGS. 8 and 9.

Hereinafter, a method for preparing the support substrate 11 provided by the embodiment of the disclosure is illustrated by taking magnesia-alumina spinel as an example. The method includes the following steps S1 to S5.

S1, magnesia-alumina spinel powder is selected for particle size screening, and the powder with a target particle size is screened out.

S2, cold isostatic pressing (CIP) is performed on the powder with the target particle size to press the powder into a blank.

S3, hot isostatic pressing (HIP) operation is performed on the magnesia-alumina spinel blank to obtain a molded magnesia-alumina spinel ingot (at this time, the grain boundary proportion has been formed).

S4, multi-wire cutting is performed on the magnesia-alumina spinel ingot to obtain a spinel cutting substrate, and then the substrate is ground.

S5, the ground spinel substrate obtained in S4 is polished to obtain the support substrate 11.

Specifically, the target particle size in step S1 is, for example, in the range of 0.1 μm to 100 μm. The temperature of the CIP in step S2 is in the range of 1400° C. to 1500° C., and the pressing pressure of the CIP in step S2 is in the range of 10000 pound force per square inch (Psi) to 100000 Psi. The temperature of the HIP in step S3 is in the range of 1650° C. to 1850° C. and the ambient pressure in step S3 is in the range of 150 Mpa to 250 Mpa. In step S4, the thickness of the spinel cutting substrate is, for example, in the range of 250 μm to 350 μm, and the preferred grinding method is to use silicon carbide or boron carbide powder with a particle size of 1200-1500 #(mesh). The polished surface in step S5 is used for bonding with the piezoelectric layer, the roughness Sa of the surface of the support substrate (i.e., the main support surface 111) obtained in step S5 is less than or equal to 0.6 nm, the total thickness variation (TTV) is less than or equal to 2 μm, and the final thickness of the spinel substrate (i.e., the support substrate 11) is in the range of 200 μm to 250 μm.

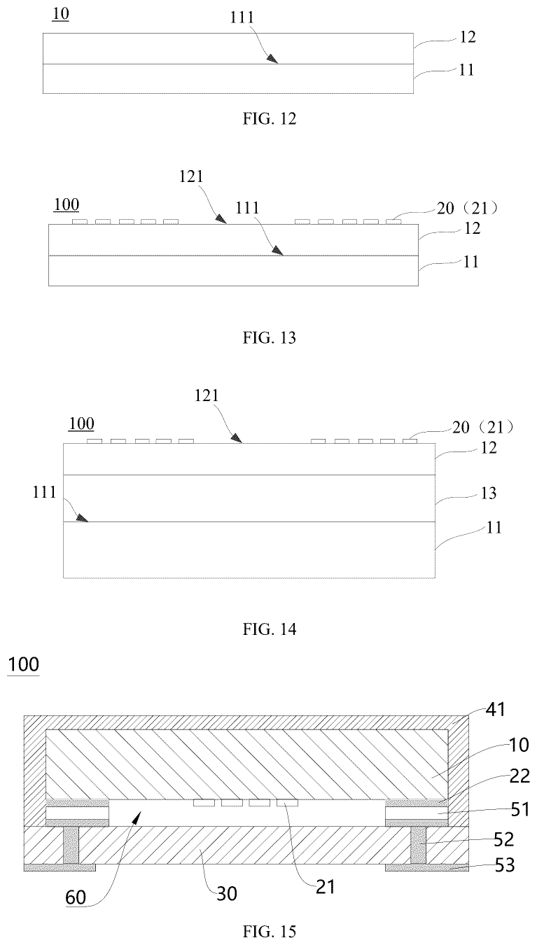

Referring to FIG. 12, an embodiment of the disclosure further provides a composite substrate 10, which includes a piezoelectric layer 12 and the support substrate 11 described in the aforementioned embodiment, and the piezoelectric layer 12 is disposed on the support substrate 11. In some embodiments, the piezoelectric layer 12 is bonded to the support substrate 11. Specifically, the piezoelectric layer 12 is bonded to the main support surface 111 of the support substrate 11, and they can be directly bonded by van der Waals force. The piezoelectric layer 12 can be, for example, made from lithium tantalate or lithium niobate. The composite substrate 10 using the support substrate 11 has at least the same spurious suppression effect as the support substrate. Referring to FIG. 13, an embodiment of the disclosure further provides an electronic device 100, which includes the support substrate 11 described in the aforementioned embodiment or the composite substrate 10 described in the aforementioned embodiment. In the composite substrate 10, the piezoelectric layer 12 includes, for example, a main surface 121 facing away from the support substrate 11, and the electronic device 100 further includes, for example, an electrode 20 disposed on the main surface 121, the electrode 20 includes, for example, an interdigital transducer (IDT) electrode 21, and the electronic device 100 is, for example, a SAW device. The electronic device 100 is provided with the support substrate 11 in the aforementioned embodiment, and has the same spurious suppression effect as the support substrate 11.

Referring to FIG. 14, an electronic device 100 (composite substrate 10) in another embodiment of the disclosure further includes an intermediate layer 13 disposed between the piezoelectric layer 12 and the support substrate 11. The sound velocity of the intermediate layer 13 is lower than that of the piezoelectric layer 12. Namely, the sound velocity of the bulk wave in the intermediate layer 13 is lower than that of the bulk wave propagating in the piezoelectric layer 12. In this embodiment, by providing the intermediate layer 13 with low sound velocity, the sound velocity of elastic waves can be reduced, and the energy of elastic waves can be concentrated in the medium with low sound velocity (i.e., the intermediate layer 13), so that the loss can be reduced and the Q value can be improved.

The material of the intermediate layer 13 is silicon oxide, silicon oxynitride, tantalum oxide or any one of these materials as the main components. In some embodiments, the intermediate layer is made of silicon oxide, and the piezoelectric layer 12 is made of lithium tantalate. The elastic constant of the lithium tantalate has a negative temperature characteristic, while silicon dioxide has a positive temperature characteristic, so that the absolute value of temperature coefficients of frequency (TCF) (also referred to as temperature drift coefficient) of the elastic wave device can be reduced. Furthermore, the inherent acoustic impedance of silicon oxide is smaller than that of lithium tantalate, so the electromechanical coupling coefficient of electronic components can be increased.

In some embodiments, the thickness of the intermediate layer 13 is greater than or equal to 0.5λ, where λ is the wavelength of the elastic wave determined by the electrode period of the IDT electrode 21. Specifically, the thickness of the intermediate layer 13 may be in the range of 0.6λ to 0.8λ. In some embodiments, the thickness of the piezoelectric layer 12 is less than or equal to 2λ. Specifically, the thickness of the piezoelectric layer 12 may be less than 1λ. In a specific embodiment, λ is 2.25 μm, the thickness of the piezoelectric layer 12 is the range of 0.1λ to 1λ, and the thickness of the intermediate layer 13 is 0.6λ.

The electronic device 100 provided in this embodiment can be packaged through chip scale package (CSP) or wafer level package (WLP).

For example, referring to FIG. 15, FIG. 15 illustrates a structural schematic diagram of an electronic device 100 packaged through CSP. The electronic device 100 includes the component (including the composite substrate 10 and the electrode 20), a package substrate 30, a first sealing structure 41 and a first external terminal electrode 53. The package substrate 30 is opposite to the surface where the electrode 20 of the component is located (that is, the main surface 121 of the piezoelectric layer 12), and a gap 60 is defined between the package substrate 30 and the main surface 121. The first sealing structure 41 is disposed on the side of the package substrate 30 facing towards the component, covering the side of the component and the side facing away from the package substrate 30 to seal the gap 60 and seal the component. The electrode 20 includes an electrode pad 22 electrically connected to the IDT electrode 21. The electrode pad 22 is electrically connected to a first conductive part 52 in the wiring pattern on the package substrate 30 through a bump 51, and the first conductive part 52 is electrically connected to the first external terminal electrode 53 on the side of the package substrate 30 facing away from the component, so that the electronic device 100 can be electrically connected to an external device through the first external terminal electrode 53.

Specifically, the materials of the package substrate 30 and the first sealing structure 41 can refer to the common substrate material and sealing material used in the existing CSP, and the electrode pad 22, the bump 51, the first conductive part 52 and the first external terminal electrode 53 are all materials with good conductivity. This embodiment is not limited to the above examples.

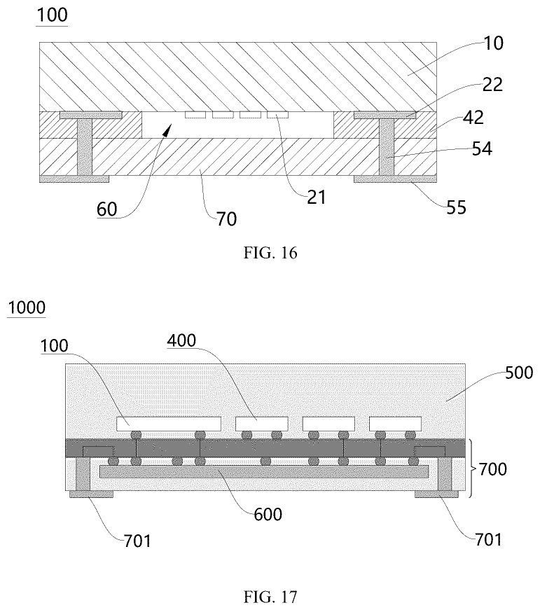

Referring to FIG. 16, FIG. 16 illustrates a structural schematic diagram of an electronic device 100 packaged through CSP. The electronic device 100 includes the component (including the composite substrate 10 and the electrode 20), a cover 70, a second sealing structure 42 and a second external terminal electrode 55. The cover 70 is arranged opposite to the surface of the component where the electrode 20 is arranged (that is, the main surface 121 of the piezoelectric layer 12), and a gap 60 is defined between the cover 70 and the main surface 121. The electrode 20 includes an electrode pad 22 electrically connected to the IDT electrode 21, and the area where the IDT electrode 21 is arranged on the main surface 121 is called an effective area, and the second sealing structure 42 is arranged between the cover 70 and the component and around the effective area. The second sealing structure 42 surrounds the electrode pad 22 to seal the component. The second external terminal electrode 55 arranged on the surface of the cover 70 facing away from the component is connected with the electrode pad 22 through the second conductive part 54 penetrating the cover 70 and the second sealing structure 42, so that the electronic device 100 can be electrically connected with an external device through the second external terminal electrode 55.

Specially, the materials of the cover 70 and the second sealing structure 42 can refer to those used in the existing WLP, and the electrode pad 22, the second conductive part 54 and the second external terminal electrode 55 are all materials with good conductivity, so this embodiment is not limited. Referring to FIG. 17, the disclosure further provides a module 1000, which includes a wiring substrate 700, multiple external connection terminals 701, an integrated circuit component 600, an electronic device 100 (including the composite substrate 10), an inductor 400 and a sealing part 500. The multiple external connection terminals 701 are formed on the surface of the wiring substrate 700, and are mounted on a motherboard of a preset mobile communication terminal. The integrated circuit component 600 (which may be called an IC) is mounted inside the wiring substrate 700. The integrated circuit component 600 includes a switching circuit and a noise amplifier. The electronic device 100 is mounted on the main surface of the wiring substrate 700. The inductor 400 is used for impedance matching. For example, the inductor 400 is an integrated passive device (IPD). The sealing part 500 is used to seal multiple electronic components including the electronic device 100 on the wiring substrate 700.

The module 1000 provided in this embodiment includes the electronic device 100, that is, the support substrate 11, which has the same spurious suppression effect as the support substrate 11, and will not be described in detail here.

What is claimed is:

1. A substrate, made of a polycrystalline material, wherein a number of small-angle grain boundary with a misorientation angle of 2° to 15° in the substrate accounts for 1% to 5% of a total number of grain boundaries.

2. The substrate as claimed in claim 1, wherein the substrate has a main support surface, a number of small-angle grain boundaries in one of a transverse section and a transverse surface of the substrate accounts for 1% to 5% of the total number of the grain boundaries, the transverse surface is the main support surface or parallel to the main support surface, and the transverse section is parallel to the main support surface.

3. The substrate as claimed in claim 1, wherein a number of small-angle grain boundaries on any surface of the substrate accounts for 1% to 5% of the total number of the grain boundaries.

4. The substrate as claimed in claim 1, wherein a number of small-angle grain boundaries in any metering area on any surface of the substrate is greater than or equal to 5, and the metering area is an area with a length of 150 μm and a width of 150 μm.

5. The substrate as claimed in claim 4, wherein a grain size of grains in the substrate is in a range of 5 μm to 60 μm, and a number of small-angle grain boundaries in any metering area on any surface of the substrate is greater than or equal to 25.

6. The substrate as claimed in claim 4, wherein a grain size of grains in the substrate is in a range of 1 μm to 5 μm, and a number of small-angle grain boundaries in any metering area on any surface of the substrate is greater than or equal to 40.

7. The substrate as claimed in claim 1, wherein the number of the small-angle grain boundary with the misorientation angle of 2° to 15° in the substrate accounts for 3% to 4% of the total number of the grain boundaries.

8. The substrate as claimed in claim 1, wherein a distribution peak of the misorientation angle in the substrate is in a range of 30° to 60°.

9. The substrate as claimed in claim 1, wherein the polycrystalline material is one selected from the group consisting of polycrystalline magnesia-alumina spinel, polycrystalline sapphire, polycrystalline aluminum nitride, polycrystalline magnesium oxide and polycrystalline quartz.

10. The substrate as claimed in claim 1, wherein a number of small-angle grain boundaries with a misorientation angle of 2° to 15° is greater than or equal to 5 in any metering area on any surface of the substrate, and the metering area is an area with a length of 150 μm and a width of 150 μm; and the polycrystalline material is one selected from the group consisting of polycrystalline magnesia-alumina spinel, polycrystalline sapphire, polycrystalline aluminum nitride, polycrystalline magnesium oxide and polycrystalline quartz.

11. The substrate as claimed in claim 10, wherein the number of the small-angle grain boundary with the misorientation angle of 2° to 15° in the substrate accounts for 3% to 4% of the total number of the grain boundaries.

12. The substrate as claimed in claim 10, wherein a distribution peak of the misorientation angle in the substrate is in a range of 30° to 60°.

13. The substrate as claimed in claim 1, further comprising a piezoelectric layer disposed on the substrate.

14. An electronic device, comprising the substrate as claimed in claim 13.

15. The electronic device as claimed in claim 14, further comprising an interdigital transducer (IDT) electrode, wherein the IDT electrode is disposed on a main surface of the piezoelectric layer facing away from the substrate.

16. The electronic device as claimed in claim 15, further comprising an intermediate layer disposed between the piezoelectric layer and the substrate, and a sound speed of the intermediate layer is lower than that of the piezoelectric layer.

17. The electronic device as claimed in claim 16, wherein a thickness of the intermediate layer is greater than or equal to 0.5λ, where λ is a wavelength of an elastic wave determined by an electrode period of the IDT electrode.

18. The electronic device as claimed in claim 15, wherein a thickness of the piezoelectric layer is smaller than or equal to 2λ, where λ is a wavelength of an elastic wave determined by an electrode period of the IDT electrode.

19. A module, comprising a wiring substrate, a plurality of external connection terminals, an integrated circuit component, an inductor, a sealing part, and the electronic device as claimed in claim 14.

20. The module as claimed in claim 19, wherein the electronic device comprises an IDT electrode disposed on a main surface of the piezoelectric layer facing away from the substrate, and a thickness of the piezoelectric layer is smaller than or equal to 2λ, where λ is a wavelength of an elastic wave determined by an electrode period of the IDT electrode.
